(19) United States
(12) Patent Application Publication
(10) Pub. No.: US 2005/0017306 A1
(43) Pub. Date: Jan. 27, 2005

(54) Semiconductor integrated circuit

(75) Inventor: Yasuyuki Morishita, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 10/894,016

(22) Filed: Jul. 20, 2004

(30) Foreign Application Priority Data
Jul. 22, 2003 (JP) 2003-277461

(51) Int. Cl. H01L 23/62

(52) U.S. Cl. 257/355

(57) ABSTRACT

To provide an output circuit having a low parasitic capacitance and resistance in the drains of output transistors, which is operable at a high speed and its ESD performance is improved. A devoted electrostatic discharge protection circuit is provided between the output terminal (pin) and the ground terminal (or power supply terminal). An output circuit which is in parallel connected to this electrostatic discharge protection circuit comprises a first and second MOS transistors which are cascade-connected to each other. The entire area of the source/drain regions of the first and second MOS transistors are silicided. Both transistors have their gate electrodes which are connected to an internal circuit. The source doped region of the first MOS transistor is separated from the drain doped region of the second MOS transistor and they are connected to each other by metal wiring.

### FIELD OF THE INVENTION

The present invention relates to a semiconductor integrated circuit and in particular to a semiconductor integrated circuit having high speed output circuitry, the electrostatic discharge performance of which is improved.

### BACKGROUND OF THE INVENTION

Recently, the sizes of MOS transistors which form semiconductor integrated circuits have been made smaller. The fact that the reduced thickness of the gate insulating films and the shallow PN junctions of the transistors, which is associated with the reduction in the size thereof makes it more difficult to prevent the semiconductor integrated circuit from damaging due to electrostatic discharge (ESD). An improvement in performance of the ESD protection circuit is essential to prevent breakdown due to electrostatic discharge.

In order to make the resistance of the source-drain diffused layer lower in a association with reduction in size, a technique to provide a silicide layer on the diffused layer, which is silicided with cobalt silicide or titanium silicide and the like has been adopted. In the silicided MOS transistors, the ESD performance is remarkably lowered since an ESD current is concentrated in the silicide film having a lower resistance. Accordingly, in order to prevent the MOS transistors which are connected to an output pin from being damaged due to electrostatic discharge (ESD), a high resistance region is provided between the drain diffused layer and the output pin in the semiconductor integrated circuit in which its diffused layer is silicided (refer to, for example, Patent documents 1 or 2). The patent document 1 will be described as a first prior art with reference to drawings. FIG. 6 shows an output circuitry. The integrated circuit is configured so that signals are output by a plurality of transistors Ti through Tn which are in parallel connected to each other. A resistor 32 is connected between each NMOS drain and an output pin 34. The gates 40 of the plurality of transistors T1 through Tn are commonly connected to an internal circuit 41.

FIG. 7 is a sectional view showing an output transistor in patent document 1. Silicide films 54 and 58 are formed on N+ drain region 48, N+ source region 46 and N+ drain contact region 56 of an NMOS transistor which is formed on a P type substrate 220. A gate electrode 50 is connected to the internal circuit (not shown), so that a signal which is to be output from the internal circuit is supplied to the gate electrode 50. An N-well 260 below a field insulating film 55 forms a high resistance region. The N+ drain region 48 is connected to the output pin 34 via the N-well 260, N+ drain contact region 56 and the silicide film 58. In the first prior art, even if an ESD stress is applied to the output pin 34, the ESD current concentration on the silicide film can be prevented since the high resistance region is provided between the output pin 34 and N+ drain region 48. Thus, the ESD performance can be improved.

Another prior art to extend the effective gate length by making output transistors into cascade type for improving the ESD performance of the output pin is known (refer to, for example patent document 3). FIG. 8 shows the configuration of an output circuit between the output pin and a ground terminal in the second prior art. An NMOS transistor 210 which is switched in response to an output signal which is to be output from an internal circuit 215 and a NMOS transistor 211 having its gate electrode connected to a power supply terminal VDD constitute an output circuit. FIG. 9 is a plan view showing the output circuit. The NMOS transistor 210 has its drain electrode comprising N+ diffused layers 60, 64 and 68, its source electrode comprising N+ diffused layers 61, 63, 65 and 67 and its gate electrode comprising polysilicon layers 69, 72, 73 and 76, which are connected to the internal circuit (not shown). The NMOS transistor 211 has its drain electrode comprising N+ diffused layers 61, 63, 65, 67, its source electrode comprising N+ diffused layers 62 and 66 and its gate electrode comprising polysilicon layers 70, 71, 74 and 75, which are connected to the power supply terminal VDD (not shown).

FIG. 10 is a sectional view taken along the line A-A′ in FIG. 9. When an ESD stress which is positive with respect to the ground terminal 32 is applied upon the output pin 33 as shown in FIG. 10 in the second prior art, a hole current due to the formation of impact ions is formed in a PN junction between the N+ diffused layer 60 and the P type silicon substrate 220. If a voltage drop occurs in a substrate resistor 241 which is parasitic in P type silicon substrate 220 due to the hole current, the potential on the point B of the P type silicon substrate 220 becomes higher than that on the ground terminal 32. When the potential on the point B becomes so higher that the PN junction between the N+ diffused layer 62 and the P type silicon substrate 220 is forwardly biased, the parasitic NPN bipolar transistor having its collection, base and emitter electrodes which comprise the N+ diffused layer, P type silicon substrate 220 and N+ diffused layer 62 respectively is turned on. Since this operation of the parasitic bipolar transistor is conducted due to the fact that the potential on point B in the P type silicon substrate 220 becomes higher relative to that on the N+ diffused layer 62 connected to the ground terminal the N+ diffused layer 61 which is not grounded hardly contributes to the operation of this parasitic NPN bipolar transistor. The ESD current is caused to flow by the above-mentioned parasitic NPN bipolar transistor. The current-voltage characteristics (I-V characteristics) at this time is schematically illustrated in FIG. 11. When the parasitic NPN bipolar transistor is turned on, a phenomenon (snapback) of exhibiting a negative resistance characteristics occurs. If the turning on current through the parasitic NPN bipolar transistor reaches a thermal limit, the output circuit is then broken down. Silicidation of the N+ diffused layer in the second prior art (relevant to 232 in FIG. 10) will remarkably lower the thermal limitation level relative to the ESD current. If no high resistance regions are disposed between the output pin 33 and the N+ diffused layers 60, 64 and 68, high ESD performance can not be assured. Both first and second prior arts are configured so that the output circuit per se functions as an ESD protection circuit.

[Patent Document 1]

U.S. Pat. No. 5,019,888 (pages 5, 6 and FIGS. 2 and 3)

[Patent Document 2]

Japanese Patent Kokai Publication No. JP-A-8-55958 (page 7, FIG. 11)

[Patent Document 3]

Japanese Patent Kokai Publication No. JP-A-9-326685 (pages 4, 5 and FIGS. 1 and 3)

### SUMMARY OF THE DISCLOSURE

The above-mentioned first prior art has a problem that speeding up of the output circuit can not be achieved since the parasitic capacitance of the drain portion increases due to the N-well provided in the drain of the output transistor, so that the switching speed of the transistor is lowered. A countermeasure which is similar to that of the first prior art is also required since an ESD current flows due to the operation of the parasitic bipolar transistor in a protection element if a silicide film is formed on the diffused layer. The second prior art also can not achieve the speeding up of the output circuit. Damaging of the gate oxide film due to ESD stress between the output pin and the power supply terminal is expected since the gate electrode of the NMOS transistor which is constantly conductive is connected to the power supply terminal VDD. In the CMOS high technology of 90 nm node generation in which the thickness of the gate oxide film is about 1.6 nm, provision of a protection circuit also between the output pin and the power supply terminal is essential. Thus, formation of a parasitic capacitance due to the presence of a protection circuit between the output pin and the power supply terminal prevents speeding up of the output circuit.

In order to solve the above-mentioned problem, a semiconductor integrated circuit of the present invention has an electrostatic discharge protection circuit between an output terminal and a ground terminal; and an output circuit comprising a first and second MOS transistors which are cascade-connected between the output terminal and the ground terminal. The first MOS transistor comprises a first drain and source regions and a first gate electrode. The second MOS transistor comprises a second drain and source regions and a second gate electrode. The first drain region is connected to the output terminal. The first source region is connected to the second drain region. The second source region is connected to the ground terminal. The first and second gate electrodes are connected to an internal circuit. The first source region is separated from the second drain source. The present invention is preferable for a semiconductor integrated circuit in that the first drain, the first source, the second drain and the second source regions are silicided over the entire surface area thereof. In the present invention, a substrate contact region of the output circuit may be provided between the first source and second drain regions.

The present invention is applicable between an output terminal and a power supply terminal in a semiconductor integrated circuit. The semiconductor integrated circuit has an electrostatic discharge protection circuit between an output terminal and a ground terminal; and an output circuit comprising a third and fourth MOS transistors which are cascade-connected between the output terminal and the ground terminal. The third MOS transistor comprises a third drain and source regions and a third gate electrode. The fourth MOS transistor comprises a fourth drain and source regions and a fourth gate electrode. The third drain region is connected to the output terminal. The third source region is connected to the fourth drain region. The fourth source region is connected to the ground terminal. The third and fourth gate electrodes are connected to an internal circuit. The third source region is separated from the fourth drain source. The present invention is preferable for a semiconductor integrated circuit in that the third drain, the third source, the fourth drain and the fourth source regions are silicided over the entire surface thereof. A substrate contact region of the output circuit may be provided between the third source and fourth drain regions.

The meritorious effects of the present invention are summarized as follows.

Since the high resistance region between the output pin and the output transistor can be eliminated without sacrificing the ESD performance in accordance with the present invention, it is possible to reduce the size of the diffused layer of the MOS transistor which is connected to the output pin to the manufacturing limit for siliciding the entire area of the diffused layer. Since the gate electrodes of the output circuit is not connected to the power supply terminal and ground terminal, but all the gate electrodes are connected to the internal circuit, the ESD current to the output current is easy to uniformly flow. Accordingly, ESD damage of the output circuit per se can be prevented and the ESD protection circuit between the output pin and the power supply terminal can be eliminated. Therefore, the capacitance and resistance of the parasitic diffused layer in the output circuit can be made very low, so that high speed operation of the output circuit can be made possible. In the prior art, if the Human-Body-Model electrostatic discharge withstand voltage (HBM-ESD withstand voltage) is 200 V in the output pin of the 90 nm node CMOS semiconductor integrated circuit, a parasitic capacitance of about 4 PF occurs. High speed operation is not possible unless the electrostatic discharge withstand voltage is sacrificed. However, in the output terminal to which the present invention is applied, high speed signal operation of about 10 Gbps is possible while suppressing the parasitic capacitance to 0.1 PF or less and meeting the requirement of HBM-ESD withstand voltage of 2000 V or more.

### BRIEF DESCRIPTION OF THE DRAWINGS

FIG. 1 is a circuit diagram showing main components of an embodiment of the present invention;

FIG. 2 is a sectional view showing a first embodiment of the present invention;

FIG. 3 is a circuit diagram showing an electrostatic discharge protection circuit which is preferable for the present invention;

FIG. 4 is a schematic view showing the current-voltage characteristics of the output circuit and electrostatic discharge protection circuit in the embodiment of the present invention;

FIG. 5 is a sectional view showing a second embodiment of the present invention;

FIG. 6 is a circuit diagram showing a first prior art output circuit;

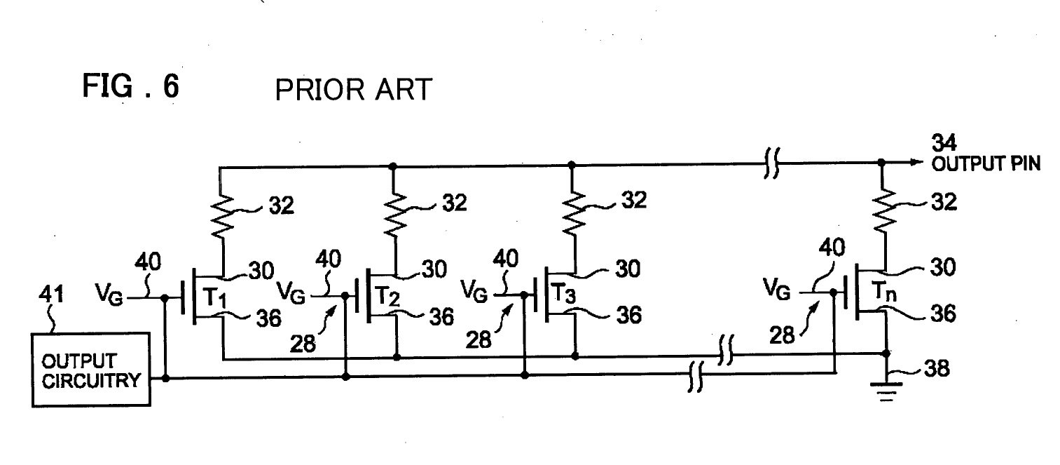

FIG. 7 is a sectional view showing a first prior art output transistor;

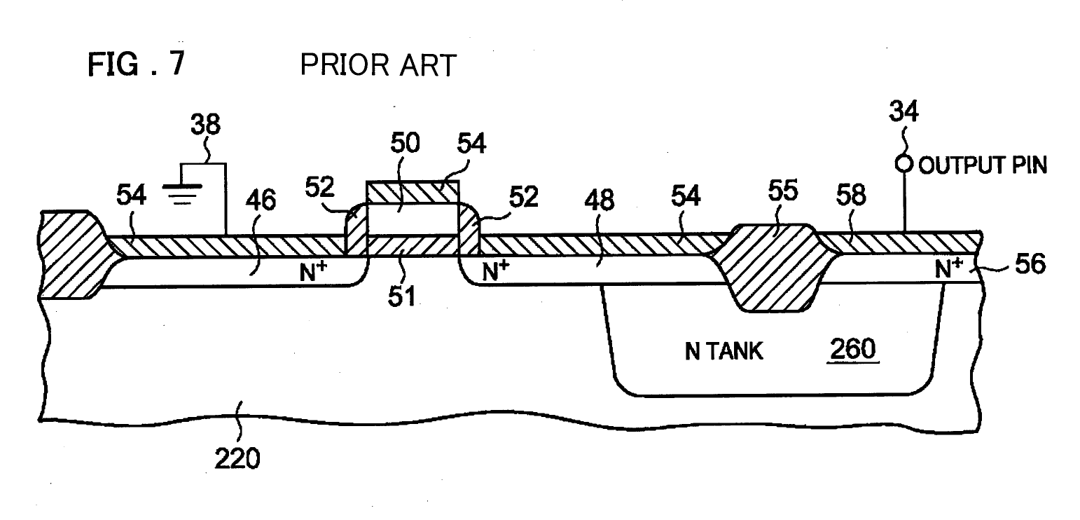

FIG. 8 is a circuit diagram showing a second prior art output circuit;

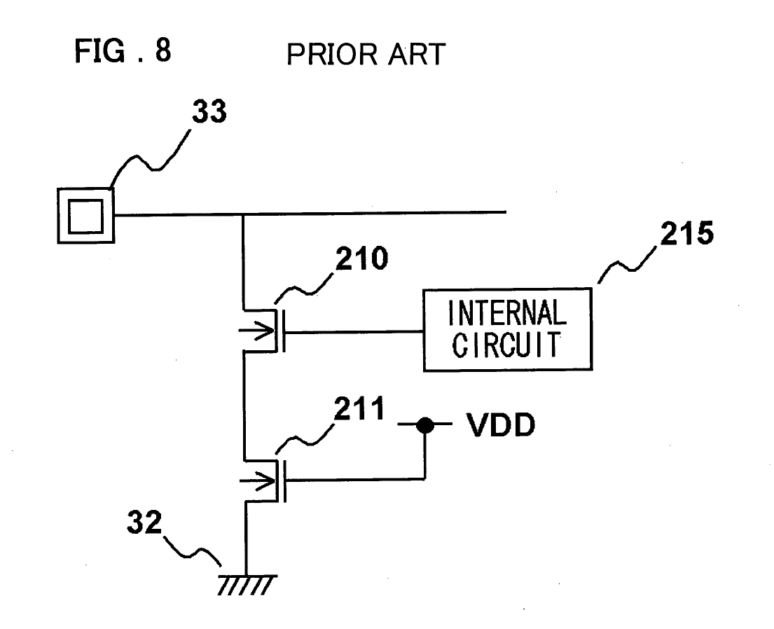

FIG. 9 is a plan view showing a second prior art output circuit;

FIG. 10 is a sectional view showing a second prior art output circuit;

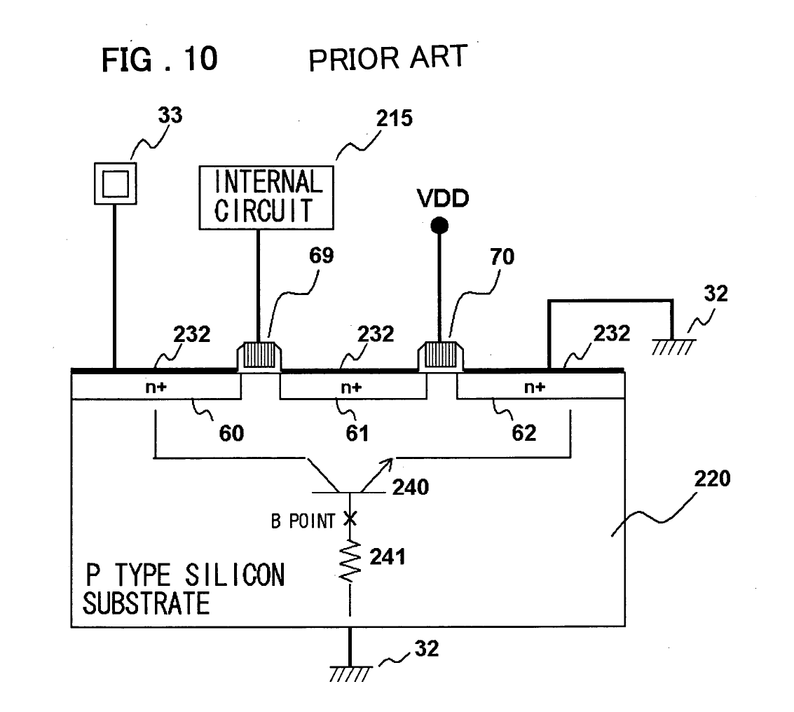

FIG. 11 is a schematic diagram showing the current-voltage characteristics in the second prior art output circuit.

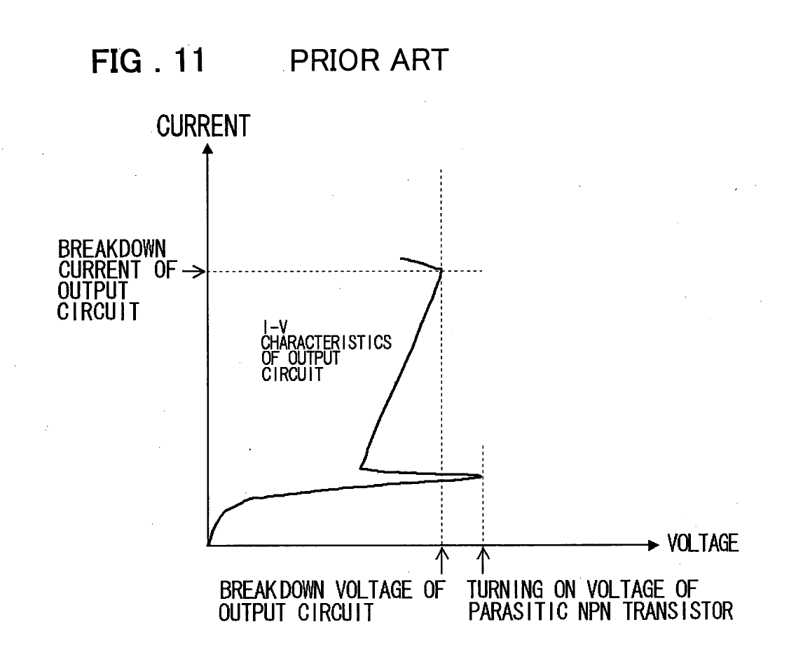

### PREFERRED EMBODIMENTS OF THE INVENTION

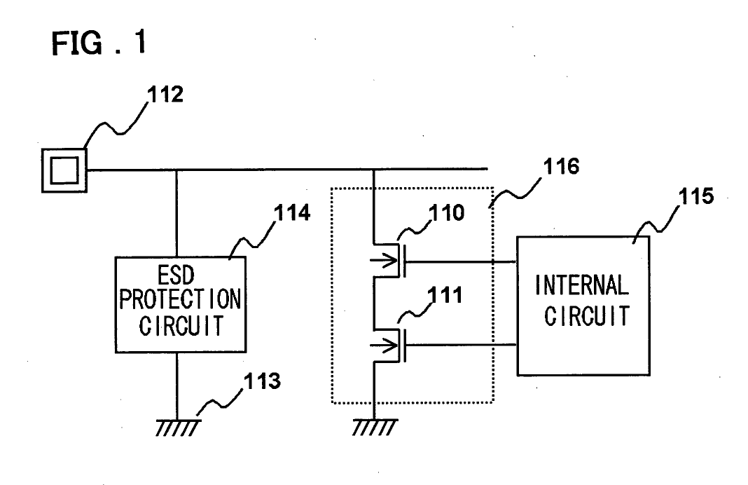

A first embodiment of the present invention will now be described with reference to the drawings. FIG. 1 is a circuit diagram showing main components of a first embodiment. A reference numeral 112 in FIG. 1 denotes an output terminal of a semiconductor integrated circuit. A numeral 114 denotes a devoted ESD protection circuit between the output pin 112 and the ground terminal 113; 115 denotes an internal circuit; 110 denotes a first NMOS transistor; 111 denotes a second NMOS transistor. The first NMOS transistor 110 is cascade connected to the second NMOS transistor 111, so that they constitute an output circuit 116 for outputting a signal from the internal circuit 115. Both first and second NMOS transistors 110 and 111 have their gate electrodes which are connected to the internal circuit 115.

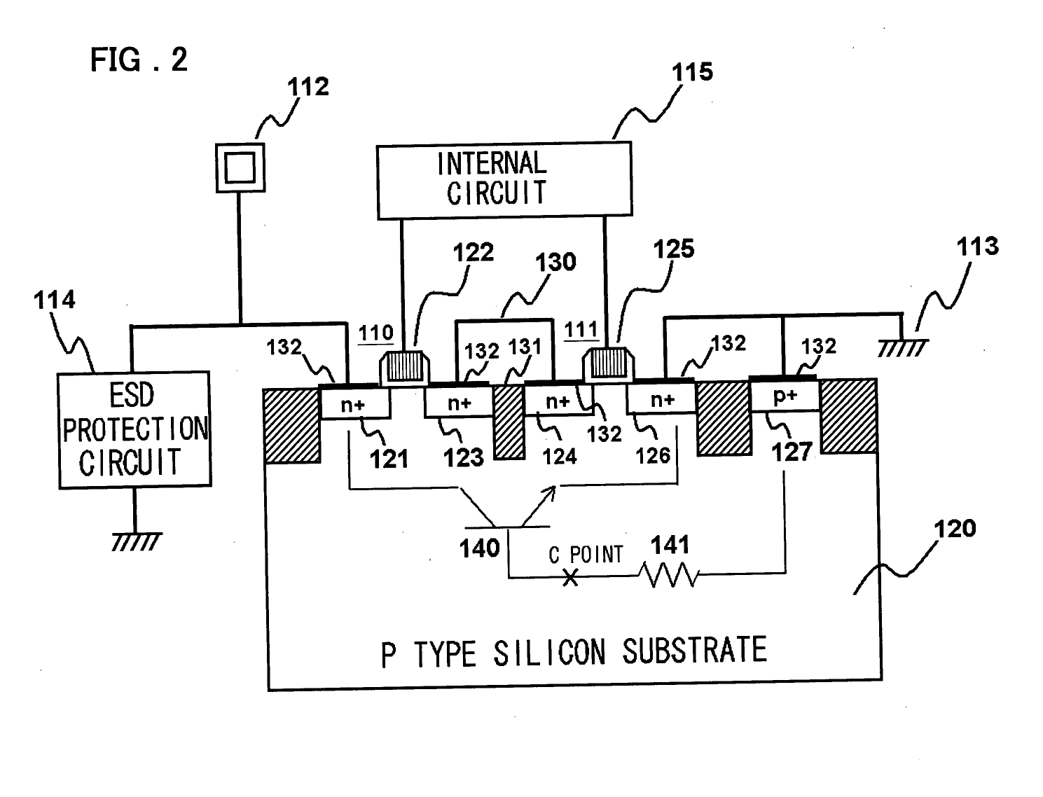

FIG. 2 is a sectional view showing main components of the first embodiment. The first and second NMOS transistors NMOS transistors 110 and 111 are formed on the P type substrate 120. Reference numerals 121 and 123 denote N+ diffused layers which form the drain and source regions of the first NMOS transistor 110, respectively. Reference numerals 124 and 126 denote N+ diffused layers which form the drain and source regions of the second NMOS transistor 111, respectively. A reference numeral 127 denotes a high concentration P+ diffused layer for bringing the output circuit into contact with the substrate. Silicide films of cobalt silicide are formed over the entire surface of the diffused layers. The drain region 121 of the first NMOS transistor 110 is connected to the output pin 112 via a silicide film 132. The source region 123 of the first NMOS transistor 110 is connected to the drain region 124 of the second NMOS transistor 111 via the silicide film 132 and a metal wiring 130. The source region 123 of the first NMOS transistor 110 is separated from the drain region 124 of the second NMOS transistor 111 by a shallow trench isolation 131. The source region 126 and high concentration P+ diffused layer 127 of the second NMOS transistor 111 are connected to the ground terminal 113. The first and second NMOS transistors 110 and 111 have their gate electrodes which are connected to the internal circuit 115 and are supplied with a signal therefrom.

Now, operation of the first embodiment will be described. Since the gate electrodes 122 and 125 of the first and second NMOS transistors 110 and 111 are connected to the internal circuit and are not short-circuited to the ground terminal in FIG. 2, a channel layer is liable to be formed below the gate electrode when an ESD stress which is positive relative to the ground terminal 113 is applied to the output pin 112 and a current flows from the N+ diffused layer 121 to the ground terminal 113 via a channel layer (not shown) of the first NMOS transistor 110, the N+diffused layer 123, the silicide film 132, the metal wiring 130, the silicide film 132, N+ diffused layer 124, a channel layer (not shown) of the second NMOS transistor 111, N+ diffused layer 126 and silicide film 132 of the second NMOS transistor 111. At this time, a hole current is generated due to the formation of impact ions in the drain region 121 of the first NMOS transistor. The hole current flows into the ground terminal 113 via a parasitic resistor 141 of P type silicon substrate, high concentration P+ diffused layer 127 and silicide film 132.

When the potential on point C in the P type silicon substrate 120 becomes higher than that on the ground terminal 113 due to a fall in voltage by the parasitic resistance 141, PN junction between the P type silicon substrate 120 and the N+ diffused layer 126 which is connected to the ground terminal 113 is forwardly biased. However, the parasitic NPN bipolar transistor 140 having a collector comprising N+ diffused layer 121, a base comprising P type silicon substrate 120 and an emitter comprising N+ diffused layer 126 is not turned on by an effect of the shallow trench isolation 131 which is provided between the N+ diffused layers 123 and 124. This is because that the current amplification efficiency β of the parasitic NPN bipolar transistor is remarkably lowered due to the fact that the carrier diffusion length in the base region (P type silicon substrate 120) from the emitter (N+ diffused layer 126) to the collector (N+ diffused layer 121) is increased by the effect of the shallow trench isolation 131.

By adopting such a configuration, the operation of the parasitic NPN bipolar transistor in the output circuit 116 when an ESD stress which is positive relative to the ground terminal 113 is applied to the output terminal 112 is prevented, so that an ESD current will flow to the ground terminal 113 via the devoted ESD protection circuit 114. Since the ESD current flowing to the output circuit is remarkably suppressed in accordance with the present invention, the output circuit is prevented from being thermally damaged even if no high resistance region can be provided between the output terminal 112 and the drain region 121 of the first NMOS transistor 110. The fact that all the gate electrodes of the output circuit are connected to the internal circuit is effective in order to allow the ESD currents in the output circuit to uniformly flow to prevent ESD damage in the output circuit. Necessity to dispose a ESD protection circuit between the output terminal and the power supply terminal is eliminated since the gate electrodes are not connected to the power supply terminal, so that the gate oxide film is not subject to any ESD stress on occurrence of ESD phenomenon between the output terminal and the power supply terminal.

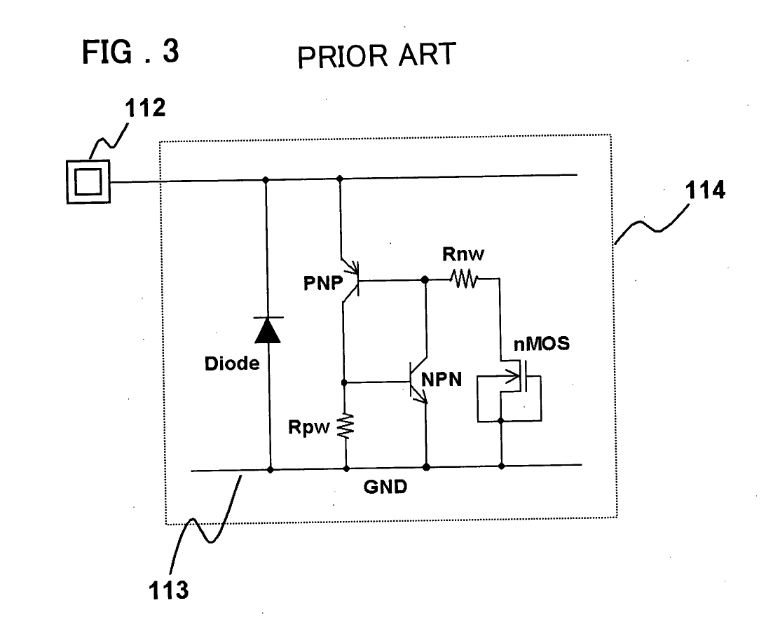

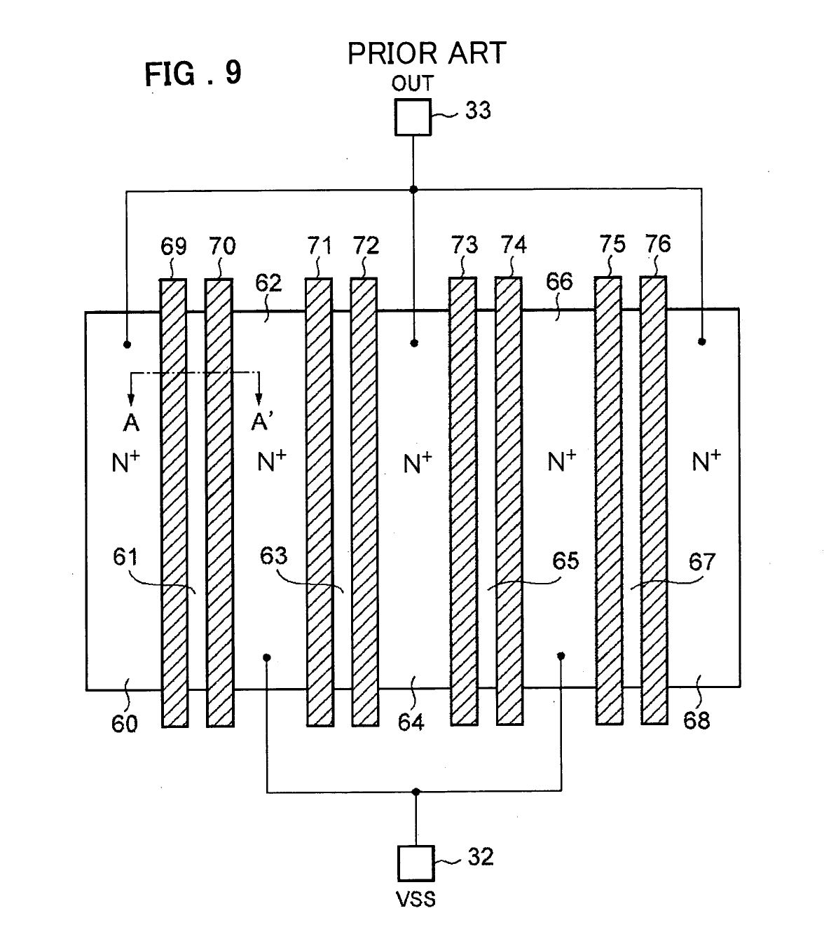

It is required that the ESD protection circuit 114 used in the present invention may be operative at a low voltage and has a high discharging capability. A protection circuit comprising a thyristor and a diode as shown in, for example, FIG. 3 is preferable as the ESD protection circuit. This protection circuit is disclosed in U.S. Pat. No. 6,545,321 (FIG. 9B).

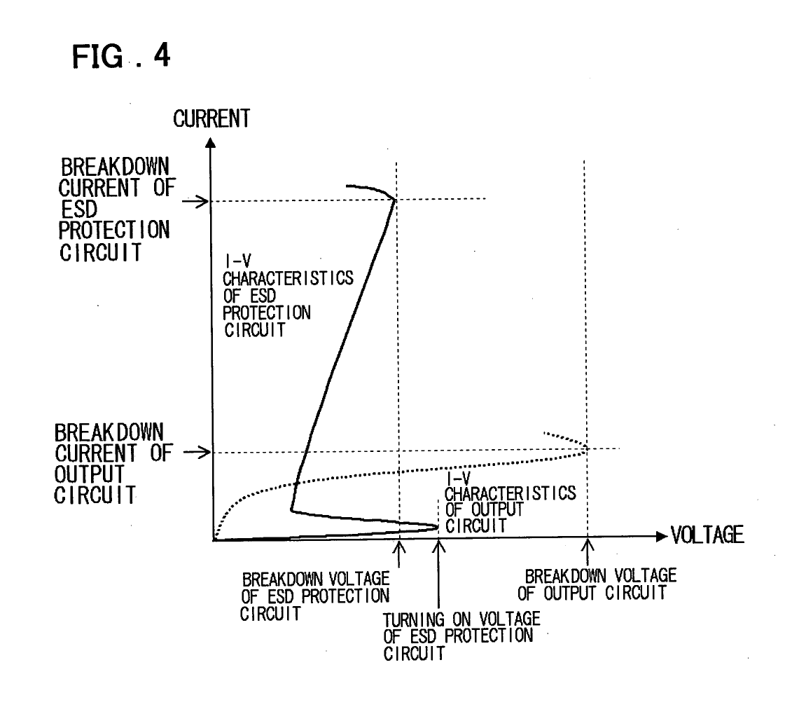

In accordance with the present invention, it is preferable that the shallow trench isolation 131 may be formed at a deeper depth in view of decreasing the current amplification efficiency β of the parasitic NPN bipolar transistor in the output circuit. In the first embodiment, the depth of the shallow trench isolation 131 is made about 0.3 μm, and the P type silicon substrate (P type well) corresponding to the base region of the parasitic NPN bipolar transistor 140 has a dope concentration of about 10¹⁷ cm⁻³ by applying 90 nm node CMOS technology. It was confirmed by an experiment that the output circuit did not cause snapback. FIG. 4 schematically shows the discharging characteristics in the first embodiment. Since all the gate electrodes in the output circuit are connected to the internal circuit, currents begin to uniformly flow. Since no snap back occurs, the breakdown voltage level increases. The applied ESD protection circuit has a turning on voltage which is lower than the breakdown voltage of the output circuit. The dimensions of the ESD protection circuit are preset so that a desired ESD current can flow at a voltage lower than the breakdown voltage level of the output circuit. Therefore, breaking down of the output circuit by the ESD current is prevented and it is not necessary to provide a high resistance region such as N-well between the output terminal 112 and the drain region 121 of the first NMOS transistor 110.

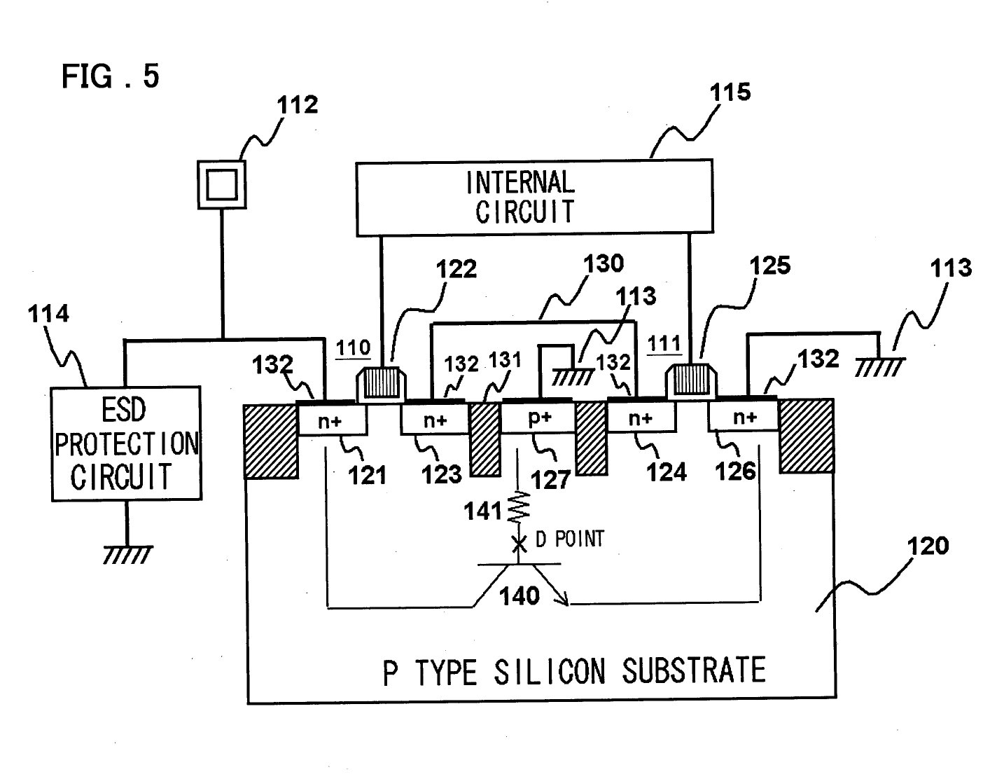

FIG. 5 is a sectional view showing a second embodiment of the present invention. In the second embodiment, a high concentration P type diffused layer 127 which will be in contact with the substrate of the output circuit is disposed between the N+ diffused layer 123 which becomes the source region of the first NMOS transistor 110 and the N+ diffused layer 124 which becomes the drain region of the second NMOS transistor 111 and is connected to the ground terminal. The other configuration is identical with that of the first embodiment. In the second embodiment, the level of the parasitic resister 141 of the P type silicon substrate can be made lower than that of the first embodiment. Accordingly, even if the depth of the shallow trench isolation 131 between the N+ diffused layers 123, 124 and the higher concentration P type diffused layer 127 is less than that in the first embodiment, turning on of the parasitic NPN bipolar transistor 140 can be prevented. It was confirmed by an experiment that discharging characteristics similar to those of the first embodiment can be obtained even if the depth of the shallow trench isolation is 0.2 μm.

The present invention has been described by way of embodiments. It is to be noted that the present invention is not limited to these embodiments and various modifications and alternations are possible without departing from the scope and spirit of the present invention. For example, the conductivity type of each substrate and diffused layer is not limited to those disclosed in the foregoing embodiments. Opposite type conductivity type can be used. Cascade-connected transistors are provided between the output terminal and ground terminal in the embodiments. They may be provided between the output terminal and power supply terminal (VDD). In this case, a first PMOS transistor and a second PMOS transistor are formed within a N-well of opposite conductivity type to a P-type substrate. High concentration N+ diffused layer is represented as a well contact that the well is a power supply potential.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

1. A semiconductor integrated circuit formed on a semiconductor substrate, comprising:
an electrostatic discharge protection circuit being between an output terminal and a ground terminal; and
an output circuit comprising a first and second MOS transistors which are cascade-connected between said output terminal and said ground terminal, said first MOS transistor having a first drain and source regions and a first gate electrode, said second MOS transistor having a second drain and source regions and a second gate electrode, said first drain region being connected to said output terminal, said first source region being connected to said second drain region, said second source region being connected to said ground terminal, said first and second gate electrodes being connected to an internal circuit, said first source region being separated from said second drain region.

2. A semiconductor integrated circuit as defined in claim 1, wherein said first drain, said first source, said second drain and said second source regions are silicided over the entire surface area thereof.

3. A semiconductor integrated circuit as defined in claim 1, wherein a substrate contact region of said output circuit is provided between said first source and second drain regions.

4. A semiconductor integrated circuit as defined in claim 1, wherein an isolation region is provided between said first source and second drain regions.

5. A semiconductor integrated circuit as defined in claim 1, wherein a trench isolation is provided between said first source and second drain regions.

6. A semiconductor integrated circuit formed on a semiconductor substrate, comprising:
an electrostatic discharge protection circuit being between an output terminal and a power terminal; and
an output circuit having a third and fourth MOS transistors which are cascade-connected between said output terminal and said power terminal, said third MOS transistor having a third drain and source regions and a third gate electrode, said fourth MOS transistor having a fourth drain and source regions and a fourth gate electrode, said third drain region being connected to said output terminal, said third source region being connected to said fourth drain region, said fourth source region being connected to said power terminal, said third and fourth gate electrodes being connected to an internal circuit, said third source region being separated from said fourth drain region.

7. A semiconductor integrated circuit as defined in claim 6, wherein said third drain, said third source, said fourth drain and said fourth source regions are silicided over the entire surface thereof.

8. A semiconductor integrated circuit as defined in claim 6, wherein a substrate contact region of said output circuit is provided between said third source and fourth drain regions.

9. A semiconductor integrated circuit as defined in claim 6, wherein an isolation region is provided between said third source and fourth drain regions.

10. A semiconductor integrated circuit as defined in claim 6, wherein a trench isolation is provided between said third source and fourth drain regions.

11. A semiconductor integrated circuit as defined in claim 6, wherein said third MOS transistor and said fourth MOS transistor are formed within a well of opposite conductivity type to said substrate.

12. A semiconductor integrated circuit as defined in claim 11, wherein said third drain, said third source, said fourth drain and said fourth source regions are silicided over the entire surface thereof.

13. A semiconductor integrated circuit as defined in claim 11, wherein there is provided with a well contact region which supplies a power supply potential to said well.

14. A semiconductor integrated circuit as defined in claim 11, wherein an isolation region is provided between said third source and fourth drain regions.

15. A semiconductor integrated circuit as defined in claim 11, wherein a trench isolation is provided between said third source and fourth drain regions.
